(19) United States
(12) Patent Application Publication
(10) Pub. No.: US 2024/0292568 A1
(43) Pub. Date: Aug. 29, 2024

(54) Cryogenic Platform

(71) Applicant: Naval Information Warfare Center Pacific, San Diego, CA (US)

(72) Inventors: Marcio Calixto de Andrade, San Diego, CA (US); Susan A. E. Breggren, San Diego, CA (US); Anna Leese de Escobar, Encinitas, CA (US); James J. Collins, San Diego, CA (US); Mark Flemon, Lakeside, CA (US); Michael O'Brien, San Diego, CA (US)

(73) Assignee: THE UNITED STATES OF AMERICA AS REPRESENTED BY THE SECRETARY OF THE NAVY, San Diego, CA (US)

(21) Appl. No.: 18/174,758

(22) Filed: Feb. 27, 2023

(51) Int. Cl. H05K 7/20; F25D 19/00

(52) U.S. Cl. CPC H05K 7/20372; F25D 19/006

(57) ABSTRACT

A cryogenic platform includes a motor, a computer processor, and a vacuum chamber with a high temperature stage and a low temperature stage. The motor is attached to a cryocooler. The computer processor is connected via one or more connections through one or more feedthrough ports to one or more electronic devices. The vacuum chamber encloses the high temperature stage and the low temperature stage, where the high temperature stage and low temperature stage are attached to the motor via a temperature stage attachment.

### STATEMENT REGARDING FEDERALLY SPONSORED RESEARCH OR DEVELOPMENT

The invention described herein may be manufactured and used by or for the government of the United States of America for governmental purposes without the payment of any royalties thereon or therefor. Licensing and technical inquiries may be directed to the Office of Research and Technical Applications, Naval Information Warfare Center Pacific, Code 72120, San Diego, CA, 92152; (619) 553-5118; NIWC_Pacific_T2@us.navy.mil. Reference Navy Case Number 105837.

### BACKGROUND

A cryogenic cooler or cryocooler is a refrigerator designed to reach cryogenic temperatures equal to or less than 120K. Cryocoolers vary in size depending on the input and cooling power requirements. A cryocooler is a standard mechanical refrigeration platform where any type of electronic device may be cooled down, provided it functions at temperatures equal to or less than 120K. Cryocoolers are categorized according to the principle of operation that is utilized during the cooling process to achieve a temperature of equal to or less than 120K. A cryogenic fluid is compressed, precooled in a heat exchanger, and expanded to achieve a target temperature.

### DESCRIPTION OF THE DRAWINGS

Features and advantages of examples of the present disclosure will be apparent by reference to the following detailed description and drawings, in which like reference numerals correspond to similar, but in some instances, not identical, components. Reference numerals or features having a previously described function may or may not be described in connection with other drawings in which they appear.

FIG. 1 is cross-sectional view of an example of a cryogenic platform described herein without a radome;

FIG. 2 is a cross-sectional view of an example of the cryogenic platform described herein with a radome attached to the vacuum chamber via a rigid radome wall; and

FIG. 3 is a cross-sectional view of an example of the cryogenic platform described herein with two radomes attached to the vacuum chamber where one radome has a flexible radome wall and another radome is attached with no radome wall.

### DETAILED DESCRIPTION

Currently, low temperature electronic devices are designed to operate in cryogenic platforms that are regulated to function at the single specific temperature required for proper functioning of the device. Different cryogenic devices that require distinct operating temperatures will each require an independent cryogenic platform. These cryogenic platforms are connected to a cryocooler (i.e., cold-head). A cryocooler can have one or two temperature stages depending on the desired target temperature. Each cryocooler requires supporting equipment to properly operate and maintain the target temperature. Therefore, in the case of devices that operate under different temperatures, each individual device will require a dedicated cryocooler. Consequently, multiple, separate, and distinct cryogenic platforms are needed to maintain each electronic device at its target temperature. For example, if two devices need to be cooled to two separate temperatures, two distinct cryocoolers are used to cool each device to their respective temperatures. Utilizing many independent cryocoolers, to accommodate various operating temperatures is inefficient and expensive when compared to the cryogenic platform described herein. In addition, since traditional cryocoolers can only set a single temperature at the lowest temperature stage, individual cryogenic platforms cannot accommodate different temperatures within a single cryogenic platform, which limits the applications compared to the cryogenic platform described herein.

The cryogenic platform herein engineers any cryocooler (i.e., cold-head) that operates based on two temperature stages to leverage each temperature stage into a source of distinct temperature stages called “child-stages”. Each child-stage is independently controlled with a single cryocooler. Each child-stage operates at a different temperature, thereby allowing cryogenic devices that operate at different temperatures with a single cryocooler, rather than multiple, separate, and distinct cryogenic platforms with individual cryocoolers. As a result, the cryogenic platform herein is more efficient and less expensive compared to the traditional cryogenic platform. Furthermore, the cryogenic platform herein can allow for expanded applications of cryogenic devices by simultaneously incorporating multiple devices, with different characteristics into the same platform.

The cryogenic platform herein includes a motor, a computer processor, and a vacuum chamber with a high temperature stage and a low temperature stage. The motor is attached to a cryocooler. The computer processor is connected via one or more connections through one or more ports to one or more electronic devices. The vacuum chamber encloses the high temperature stage and the low temperature stage, where the high temperature stage and low temperature stage are attached to the motor via a temperature stage attachment.

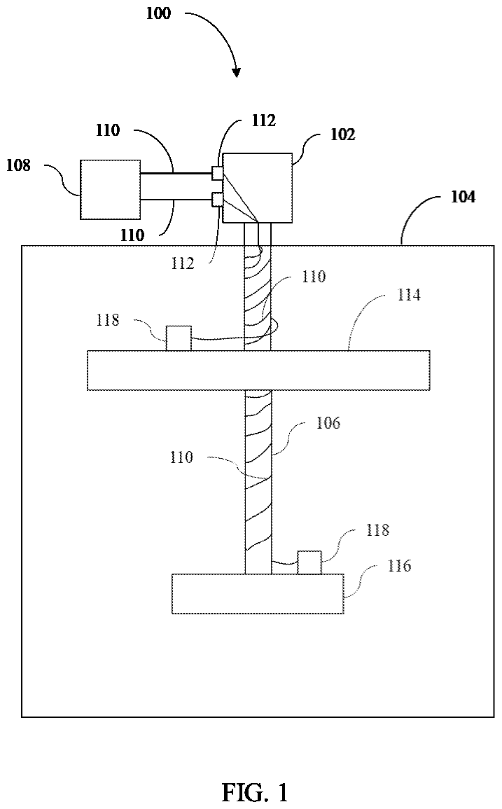

Referring now to FIG. 1, the cryogenic platform 100 includes a motor 102 where the motor 102 attaches to a cryocooler (not shown in FIG. 1). The motor 102 also attaches to a vacuum chamber 104. In some examples, the motor 102 moves cooling fluid through the system. However, depending on the cryogenic platform 100, the motor 102 may perform other functions as well. In some examples, as shown in FIG. 1, the motor 102 includes one or more feedthrough ports 112 that allow the computer processor 108 to be connected via one or more connections 110 to the feedthrough ports 112. In other examples, the motor 102 has no feedthrough ports 112. The required cooling power depends on the heat load of the components and devices mounted in the vacuum chamber 104. For example, if the combined platform heat load is larger, the cryocooler needs a higher cooling power in order to make the temperature stage reach the desired temperature. In an example, the cryocooler can have a cooling power of about 6 watts at 20 kelvin or about 1 watt at 4 kelvin.

The feedthrough ports 112 make the connection between the exterior of the cryogenic platform 100 and the vacuum chamber 104. As a result, the feedthrough ports 112 link external devices (e.g., a computer processor 108) to internal electronics within the vacuum chamber 104 to control the motor 102 and cryogenic platform 100 operation. In other examples, the feedthrough ports 112 also link the computer processor 108 to the electronic devices 118 within the vacuum chamber 104. The feedthrough ports 112 are capable of connecting to the interior components of the cryogenic platform 100 without compromising the integrity of the vacuum chamber 104. The feedthrough ports 112 can be any ports that support the one or more connections 110. For example, the feedthrough ports 112 may be feedthrough ports 112 for one or more coax cables, one or more single pair direct current cables, one or more twisted pair direct current cables, one or more optic cables, or a combination thereof.

Referring back to FIG. 1, the cryogenic platform includes a computer processor 108. The computer processor 108 is connected via one or more connections 110 to control the motor 102 and cryogenic platform 100 operation. A computer processor 108 can also be utilized to operate in conjunction with one or more electronic devices 118. In the latter case, the computer processor 108 executes the typical operations and tasks of a central processing unit (CPU). In an example, the computer processor 108 may be any computer processor 108 capable of storing and analyzing data from the one or more electronic devices 118.

In one example, the one or more connections 110 connect the one or more electronic devices 118 within the vacuum chamber 104 to the computer processor 108 outside the vacuum chamber 104 via the feedthrough ports 112. In an example, there is at least one connection between each electronic device 118 and the computer processor 108. In other examples, there is two or more connections 110 between an electronic device 118 and the computer processor 108. In another example, the one or more connections 110 connect the computer processor 108 to the internal electronic components to control the motor 102 and cryogenic platform operation via the feedthrough ports 112. In an example, the one or more connections 110 are one or more coax cables, one or more single pair direct current cables, one or more twisted pair direct current cables, one or more optic cables, or a combination thereof. In some examples, the one or more connections 110 wrap around the temperature stage attachment 106, which can be made of the same material that may be used for the high temperature stage 114, the low temperature stage 116, or the cold finger 208 discussed below, for heat sinking purposes and attach to one of the one or more feedthrough ports 112, as shown in FIG. 1.

The one or more electronic devices 118 can vary depending on the application of the cryogenic platform 100. In an example, the one or more electronic devices 118 may be any electronic device 118 capable of converting electromagnetic signals into a voltage and capable of functioning in the cryogenic platform 100. Some examples of the one or more electronic devices 118 include one or more superconducting electronic devices, one or more RF devices, one or more superconducting analog-to-digital converters, one or more sensors, one or more RF filters, one or more RF superconducting filters, or a combination thereof. In another example, the one or more electronic devices 118 can be any device that is compatible with the dimensions of the vacuum chamber 102 and cryocooler. In some examples, when one or more RF devices are being used to monitor electromagnetic signals originated outside the vacuum chamber 102, the vacuum camber 102 includes a window composed of an electromagnetically transparent material. In an example, the electromagnetically transparent material that allows a signal to pass through ranging from about 1 DC to about 10 THz. In another example, the signal may be greater than 10 THz depending on the type of device being probed.

Referring back to FIG. 1, the cryogenic platform 100 further includes a vacuum chamber 104 where the vacuum chamber 104 encloses a high temperature stage 114 and a low temperature stage 116, where the high temperature stage 114 and low temperature stage 116 are attached to the motor 102. The vacuum chamber 104 removes as much residual gases as possible to avoid compromising the vacuum state and interfering with the ability to cool down electronic devices within the vacuum chamber 104. The vacuum chamber 104 may be any shape, which may vary depending on the design requirements. The vacuum chamber 104 may be any size and material that is compatible with the cooling power associated with the cryocooler and the vacuum level requirements. The vacuum can be made of metallic, glass, or non-metallic materials depending on the application. In some examples, the vacuum chamber 104 can have one or more feedthrough ports 112 directly on the vacuum chamber 104, one or more window openings directly on the vacuum chamber 104, or a combination thereof.

Referring back to FIG. 1, the high temperature stage 114 and low temperature stage 116 are attached to the motor 102 via the temperature stage attachment 106. The high temperature stage 114 and low temperature stage 116 are set to separate, distinct temperatures ranging from about 3K to about 70K depending on the application. In an example, the high temperature stage 114 has a temperature ranging from about 40K to about 70K. In another example, the high temperature stage 114 has a temperature ranging from about 50K to about 70K. In an example, the low temperature stage 116 has a temperature ranging from about 3K to about 5K. The high temperature stage 114 and the low temperature stage 116 may be composed of the same or different material as the cold finger 208 (discussed below). Similarly, the high temperature stage 116 and the low temperature stage 114 may be the same material as each other or each temperature stage may be a different material. Additionally, the high temperature stage 114 and low temperature stage 116 can each accommodate the same or different electronic devices 118. The number of electronic devices 118 attached to the high temperature stage 114 and low temperature stage 116 may vary depending on the maximum heat load the stages can sustain without interfering with the cooling capabilities of the cryocooler.

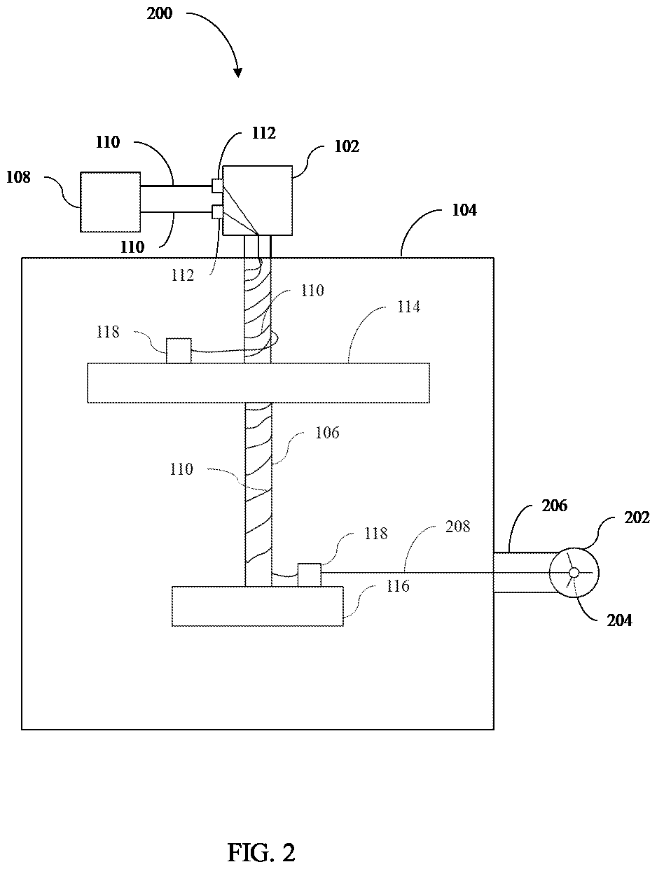

Referring now to FIG. 2, a cryogenic platform with a radome 200 is shown. The cryogenic platform 200 is the same as the cryogenic platform 100 in FIG. 1. However, the cryogenic platform 200 in FIG. 2 has a window where a radome 202 is attached to the vacuum chamber 104 via a cold finger 208. In some examples, the cryogenic platform 100 may have one or more cold fingers 208. The radome 202 preserves the vacuum while allowing electromagnetic waves to penetrate. In FIG. 2, an antenna 204 is depicted within the radome 202 that detects electromagnetic waves. However, in other examples, any device that is capable of detecting electromagnetic waves may be used rather than the antenna 204. Some examples of devices that may be used include one or more antennas, one or more sensors, or a combination thereof. The antenna 204 (or other device) is connected to the electronic device 118 via antenna sensor connections that passes through the radome wall 206 along the cold finger 208 into the vacuum chamber 104. The antenna 204 can be any type of small antenna (e.g., a single loop antenna). The antenna or sensor connection is matched to the type of antenna or sensor that is mounted inside the radome 202. For example, the antenna or sensor connection can be RF cables, fiber optics, DC cables, or a combination thereof. The electronic device 118 will then convert the electromagnetic radiation into voltage data and send the voltage data to the computer processor 108 for storage, analysis, or both. In the example shown in FIG. 2, the antenna 204 is connected to an electronic device 118 on the low temperature stage 116. In other examples, the antenna 204 (or other devices capable of detecting electromagnetic waves) may be connected to an electronic device 118 on the high temperature stage 114 or both the high temperature stage 114 and the low temperature stage 116.

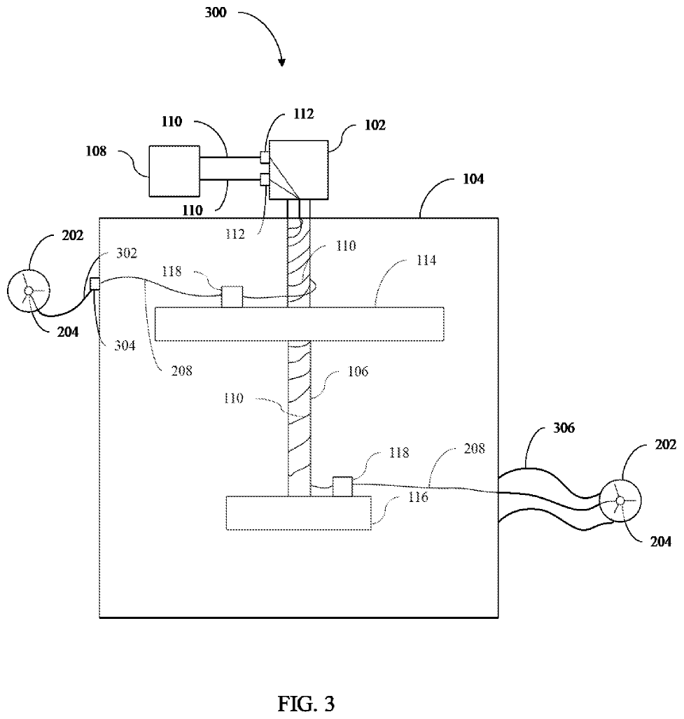

A cold finger 208 provides the connection between the vacuum chamber 104 and the radome 202. The cryogenic platform 100 may have one or more flexible or rigid cold fingers 208 depending on the application and design of the cryogenic platform 100. In an example, the cold finger 208 has a thermal conductivity equal to or greater than equal to or greater than 30 W/m·K. The cold finger 208 may be any material that has a thermal conductivity equal to or greater than 30 W/m·K. For example, the cold finger 208 may be metallic or non-metallic material depending on the application, such as sapphire (36 W/m·K), aluminum 1100 (54 W/m·K), high purity copper (320 W/m·K), or a combination thereof. Other examples of the cold finger 208 include a metal, such as gold, copper, silver, or a combination thereof. The cold finger 208 may also be non-metallic materials, such as diamond (e.g., 2000-2200 W/m·K), Aluminum nitride (e.g., 310 W/m·K), or beryllium oxide (e.g., 285 W/m·K), or a combination thereof. Additionally, the cold finger 208 may be any size or shape as long as the cold finger 208 connects the electronic device 118 to the antenna 204 (or other device) within the radome 202 by passing through the radome wall 206. In the example shown in FIG. 2, a rigid radome wall 206 is shown. However, the radome wall 206 may be a flexible radome wall 206 as well. In another example, no radome wall 206 may be used and the vacuum chamber 104 may have a vacuum chamber feedthrough port 304 to the cold finger 208 within the vacuum chamber 104 via an external connection as shown in FIG. 3.

Referring now to FIG. 3, an example of a cryogenic platform with two radomes 300 is shown. As previously stated herein, in other examples, the two antennas 204 shown in FIG. 3 may be any electronic device that is capable of detecting electromagnetic radiation. In FIG. 3, there are two radomes 202 with two antennas 204 located within the radomes 202. However, in other examples, there may be one or more radomes 202 with each radome 202 including a device capable of detecting electromagnetic radiation. For example, there may be one or more radomes 202 with one or more antennas, one or more sensors, or a combination thereof. In FIG. 3, one antenna 204 is connected to an electronic device 118 on the high temperature stage 114 via a connection 302 with no radome wall 306 that connects directly to the vacuum chamber 104 via a vacuum chamber feedthrough port 304. The other antenna 204 is connected to an electronic device 118 on the low temperature stage 116 via an antenna connection 302 that passes along a cold finger 208 and through a flexible radome wall 306. In other examples not shown in FIG. 3, any combination of electromagnetic detection device with or without a radome wall 306 may be used to connect to an electronic device 118 on either low temperature stage 116 or high temperature stage 114. There may be as many radomes 202 and electromagnetic detection devices with or without radome walls 306 that can be practically used on a cryogenic platform 100 depending on the application.

The cryogenic platforms 100, 200, 300 may also be a cryogenic platform system. The cryogenic platform system includes the same motor 102, vacuum chamber 104, cold finger 208, computer processor 108, one or more connections 110, one or more feedthrough ports 112, high temperature stage 114, low temperature stage 116, and electronic devices 118 as previously described herein in reference to FIG. 1, FIG. 2, and FIG. 3.

As used herein, the term “about” is used to provide flexibility to a numerical range endpoint by providing that a given value may be “a little above” or “a little below” the endpoint. The degree of flexibility of this term can be dictated by the particular variable and would be within the knowledge of those skilled in the art to determine based on experience and the associated description herein.

As used herein, a plurality of items, structural elements, compositional elements, and/or materials may be presented in a common list for convenience. However, these lists should be construed as though each member of the list is individually identified as a separate and unique member. Thus, no individual member of a list should be construed as a de facto equivalent of any other member of the same list merely based on their presentation in a common group without indications to the contrary.

Unless otherwise stated, any feature described herein can be combined with any aspect or any other feature described herein.

Reference throughout the specification to “one example”, “another example”, “an example”, means that a particular element (e.g., feature, structure, and/or characteristic) described in connection with the example is included in at least one example described herein, and may or may not be present in other examples. In addition, the described elements for any example may be combined in any suitable manner in the various examples unless the context clearly dictates otherwise.

The ranges provided herein include the stated range and any value or sub-range within the stated range. For example, a range from about 3K to about 70K should be interpreted to include not only the explicitly recited limits of from about 3K to about 70K, but also to include individual values, such as 13K, 27K, 57.5K, etc., and sub-ranges, such as from about 15K to about 45K, etc.

In describing and claiming the examples disclosed herein, the singular forms “a”, “an”, and “the” include plural referents unless the context clearly dictates otherwise.

What is claimed is:

1. A cryogenic platform, comprising:
a motor, wherein the motor is attached to a cryocooler;
a computer processor, wherein the computer processor is connected via one or more connections through one or more feedthrough ports to one or more electronic devices; and
a vacuum chamber, wherein the vacuum chamber encloses:
a high temperature stage and a low temperature stage, wherein the high temperature stage and low temperature stage are attached to the motor via a temperature stage attachment.

2. The cryogenic platform of claim 1, wherein the one or more electronic devices are one or more superconducting electronic devices, one or more RF devices, one or more superconducting analog-to-digital converters, one or more RF filters, one or more RF superconducting filters, one or more sensors, or a combination thereof.

3. The cryogenic platform of claim 1, wherein the high temperature stage and low temperature stage are the same or different material as each other with a thermal conductivity equal to or greater than 30 W/m·K.

4. The cryogenic platform of claim 1, wherein the one or more connections wrap around the temperature stage attachment and attach to one of the one or more feedthrough ports.

5. The cryogenic platform of claim 1, wherein the high temperature stage ranges from about 40K to about 70K.

6. The cryogenic platform of claim 1, wherein the low temperature stage ranges from about 3K to about 5K.

7. The cryogenic platform of claim 1, further including one or more radomes where each radome includes an antenna, one or more sensors, or a combination thereof enclosed in a flexible or rigid radome wall.

8. The cryogenic platform of claim 7, wherein the antenna, one or more sensors, or the combination thereof are connected to the one or more electronic devices via one or more antenna or sensor connections where the one or more antenna or sensor connections pass along a rigid cold finger, a flexible cold finger, a vacuum chamber port, or a combination thereof.

9. The cryogenic platform of claim 1, further including one or more flexible or rigid cold fingers that have a thermal conductivity equal to or greater than 30 W/m·K.

10. The cryogenic platform of claim 1, wherein the one or more connections are one or more coax cables, one or more single pair direct current cables, one or more twisted pair direct current cables, one or more optic cables, or a combination thereof.

11. A cryogenic platform system, comprising:
a motor, wherein the motor is attached to a cryocooler;
a computer processor, wherein the computer processor is connected via one or more connections through one or more feedthrough ports to one or more electronic devices; and
a vacuum chamber, wherein the vacuum chamber encloses:
a high temperature stage and a low temperature stage, wherein the high temperature stage and low temperature stage are attached to the motor via a temperature stage attachment.

12. The cryogenic platform of claim 11, wherein the one or more electronic devices are one or more superconducting electronic devices, one or more RF devices, superconducting analog-to-digital converters, sensors, one or more RF filters, one or more RF superconducting filters, or a combination thereof.

13. The cryogenic platform of claim 11, wherein the high temperature stage and low temperature stage are the same or different material as each other with a thermal conductivity equal to or greater than 30 W/m·K.

14. The cryogenic platform of claim 11, wherein the one or more connections wrap around the temperature stage attachment and attach to one of the one or more feedthrough ports.

15. The cryogenic platform of claim 11, wherein the high temperature stage ranges from about 40K to about 70K.

16. The cryogenic platform of claim 11, wherein the low temperature stage ranges from about 3K to about 5K.

17. The cryogenic platform of claim 11, further including one or more radomes where each radome includes an antenna, one or more sensors, or a combination thereof enclosed in a flexible or rigid radome wall.

18. The cryogenic platform of claim 17, wherein the antenna, one or more sensors, or the combination thereof are connected to the one or more electronic devices via one or more antenna or sensor connections where the one or more antenna or sensor connections pass along a rigid cold finger, a flexible cold finger, a vacuum chamber port, or a combination thereof.

19. The cryogenic platform of claim 11, further including one or more flexible or rigid cold fingers that have a thermal conductivity equal to or greater than 30 W/m·K.

20. The cryogenic platform of claim 11, wherein the one or more connections are one or more coax cables, one or more single pair direct current cables, one or more twisted pair direct current cables, one or more optic cables, or a combination thereof.
